(19) United States
(12) Patent Application Publication
(10) Pub. No.: US 2016/0093465 A1
(43) Pub. Date: Mar. 31, 2016

(54) DEFECT INSPECTION APPARATUS AND DEFECT INSPECTION METHOD

(71) Applicant: KABUSHIKI KAISHA TOSHIBA, Minato-ku (JP)

(72) Inventors: Osamu NAGANO, Nagoya (JP); Atsushi ONISHI, Nagoya (JP)

(73) Assignee: KABUSHIKI KAISHA TOSHIBA, Minato-ku (JP)

(21) Appl. No.: 14/657,509

(22) Filed: Mar. 13, 2015

Related U.S. Application Data
(60) Provisional application No. 62/055,807, filed on Sep. 26, 2014.

(51) Int. Cl. H01J 37/22; H01J 37/244; H01J 37/30

(52) U.S. Cl. CPC H01J 37/222; H01J 37/30; H01J 37/244; H01J 2237/2814

(57) ABSTRACT

In accordance with an embodiment, a defect inspection method includes: generating first and second images regarding a subject with first and second patterns, extracting first coordinates of the first pattern from the first image, setting a mask region in which a predetermined margin is provided in the first coordinates, taking a difference between the second image and a reference image, and checking the difference against the mask region to detect a defect in the second pattern. The first image is generated from a signal obtained by generating a charged particle beam under a first charged particle irradiation condition and irradiating the charged particle beam to a subject. The second image is generated from a signal obtained by generating a charged particle beam under a second charged particle irradiation condition, irradiating the charged particle beam to a subject region of the subject, and detecting second charged particles generated from the subject.

### CROSS REFERENCE TO RELATED APPLICATIONS

This application is based upon and claims the benefit of U.S. provisional Application No. 62/055,807, filed on Sep. 26, 2014, the entire contents of which are incorporated herein by reference.

### FIELD

Embodiments described herein relate generally to a defect inspection apparatus and a defect inspection method.

### BACKGROUND

There is known a scanning electron microscope (SEM) type inspection technique to irradiate an electron beam to a substrate in which a pattern is formed to acquire an SEM image, compare adjacent dies or adjacent patterns, and detect a defect from a detected difference.

In a pattern in a process where wiring trenches and contact holes are fabricated together with each other on an insulating film such as an oxide film, the trenches of the wiring lines are formed in a surface of the insulating film, and the contact holes are formed in the wiring trenches in some cases. When the SEM type inspection technique is applied to this pattern, the wiring trenches and the contact holes greatly vary in contrast due to the difference of collection ratio of secondary electrons because the wiring trenches and the contact holes greatly vary in fabrication dimensions, depth, and aspect ratio.

For example, brightest contrast is obtained in the surface of the oxide film (see the sign IS in FIG. 3). The wiring trenches are designed (dimensioned) to be relatively large and fabricated to be shallow, and have a low aspect ratio, so that contrast darker than that in the surface of the oxide film is obtained for the wiring trenches (see the signs WT1 to WT6 in FIG. 3).

Furthermore, the contact holes are designed (dimensioned) to be relatively small and fabricated to be deep, and have a high aspect ratio, so that darkest contrast is obtained (see the signs CH1 to CH3 in an image Img11 in FIG. 3).

When a subject having the above-mentioned pattern is inspected for open defects and short-circuit defects in the wiring trenches as inspection targets after an optimum electron beam condition is determined, a large number of slight shape changes and displacements of the contact holes having the greatest contrast difference as compared with the surrounding parts are detected because a great difference signal is obtained if the difference of SEM images is taken between adjacent dies or adjacent patterns.

Thus, defect candidates from contact holes include many slight shape changes and displacements.

However, in many cases the slight shape changes and displacements of the contact holes have no influence on yield and fall within the designed tolerance.

Meanwhile, in general, the number of open defects and short-circuit defects in the wiring trenches as detection target defects are considerably smaller than the number of defect candidates from the contact holes. Therefore, it is difficult to extract the defects in the wiring trenches from among a large number of defect candidates.

### BRIEF DESCRIPTION OF THE DRAWINGS

In the accompanying drawings:

FIG. 1 is an example of a block diagram showing the general configuration of a defect inspection apparatus according to one embodiment;

FIG. 2A is a diagram showing an example of pattern layout in a given die formed in an example of a subject;

FIG. 2B is a diagram showing an example of a sectional view taken along the line A-A in FIG. 2A;

FIG. 3 is an example of diagrams illustrating the overview of a detect inspection using the defect inspection apparatus shown in FIG. 1;

FIG. 4A to FIG. 5C are examples of diagrams illustrating the reason why an absorbed current figure is used to set a mask region;

FIG. 6A is an example of a partial sectional view showing another example of a subject;

FIG. 6B is a diagram showing an example of a shape contrast figure obtained by irradiating an electron beam under An SEM condition with a probe current of several nA to pA order at an acceleration voltage of 1 keV or less;

FIG. 6C is a diagram showing an example of a potential contrast figure obtained by irradiating an electron beam under an SEM condition with a probe current of several ten nA order at a low acceleration voltage of 1 keV or less; and

FIG. 7 is a flowchart showing the general procedure of a defect inspection method according to one embodiment.

### DETAILED DESCRIPTION

In accordance with an embodiment, a defect inspection method includes: generating first and second images regarding a subject with first and second patterns, extracting first coordinates of the first pattern from the first image, setting a mask region in which a predetermined margin is provided in the first coordinates, taking a difference between the second image and a reference image, and checking the difference against the mask region to detect a defect in the second pattern. The first image is generated from a signal obtained by generating a charged particle beam under a first charged particle irradiation condition and by irradiating the charged particle beam to a subject. The second image is generated from a signal obtained by generating a charged particle beam under a second charged particle irradiation condition, by irradiating the charged particle beam to a subject region of the subject, and by detecting second charged particles generated from the subject. The reference image is obtained by irradiating a charged particle beam to a reference region different from the subject region based on the same layout as the subject under the second charged particle irradiation condition. The first charged particle irradiation condition is a condition in which higher contrast is obtained regarding the first pattern than the second pattern in the image obtained by irradiating the charged particle beam to the subject.

Embodiments will now be explained with reference to the accompanying drawings. Like components are provided with like reference signs throughout the drawings and repeated descriptions thereof are appropriately omitted. It is to be noted that the accompanying drawings illustrate the invention and assist in the understanding of the illustration and that the shapes, dimensions, and ratios and so on in each of the drawings may be different in some parts from those in an actual apparatus.

While an electron beam is described below as a charged particle beam by way of example, the present invention is not limited thereto and is also applicable to, for example, an ion beam.

(1) Defect Inspection Apparatus

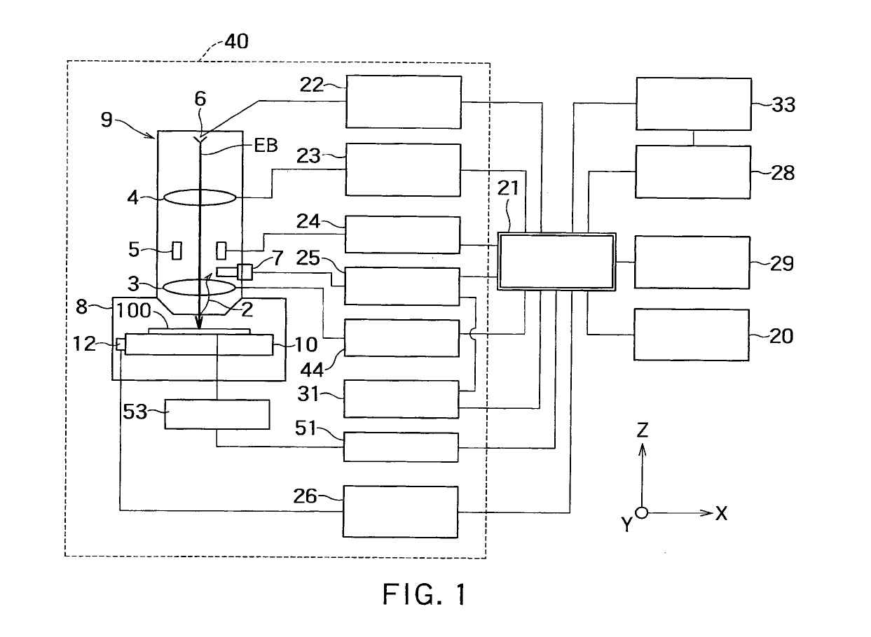

FIG. 1 is an example of a block diagram showing the general configuration of a charged particle beam apparatus according to one embodiment. The electron beam inspection apparatus shown in FIG. 1 includes a scanning electron microscope 40, a control computer 21, a defect detection unit 33, a storage device 28, a display device 29, and an input device 20. The control computer 21 is connected to the defect detection unit 33, the storage device 28, the display device 29, and the input device 20.

The scanning electron microscope 40 includes a column 9, a sample chamber 8, an electron gun control unit 22, lens control units 23 and 44, a deflector control unit 24, a signal processing unit 25, a first image generating unit 31, an absorbed current acquiring unit 53, a second image generating unit 51, and a stage control unit 26.

The column 9 is provided with an electron gun 6, a condenser lens 4, a deflector 5, an objective lens 3, and a detector 7. An actuator 12 and a stage 10 which supports a subject 100 having an inspection target pattern formed therein are provided in the sample chamber 8.

The control computer 21 is also connected to the electron gun control unit 22, the lens control units 23 and 44, the deflector control unit 24, the signal processing unit 25, the first image generating unit 31, the second image generating unit 51, and the stage control unit 26. The control computer 21 generates various control signals and then sends the control signals to the electron gun control unit 22, the lens control units 23 and 44, the deflector control unit 24, and the stage control unit 26.

The electron gun control unit 22 is connected to the electron gun 6 in the column 9. The lens control unit 23 is connected to the condenser lens 4. The lens control unit 44 is connected to the objective lens 3. The deflector control unit 24 is connected to the deflector 5. The signal processing unit 25 is connected to the detector 7. The first image generating unit 31 is connected to the signal processing unit 25. The second image generating unit 51 is connected to the absorbed current acquiring unit 53. The stage control unit 26 is connected to the actuator 12 in the sample chamber 8.

The electron gun controller 22 generates a control signal in accordance with an irradiation condition indicated by the control computer 21. In response to this control signal, the electron gun 6 generates and emits an electron beam EB. The emitted electron beam EB is focused by the condenser lens 4, and then the focal position of the electron beam EB is adjusted by the objective lens 3 so that the electron beam EB is irradiated to the subject 100.

The lens control unit 23 generates a control signal in accordance with an instruction by the control computer 21. In response to this control signal, the condenser lens 4 focuses the electron beam EB.

The lens control unit 44 generates a control signal in accordance with an instruction by the control computer 21. In response to the control signal, the objective lens 3 adjusts the focal position of the electron beam EB, and brings the electron beam EB into the surface of the subject 100 in a just-focus state.

The deflector control unit 24 generates a control signal in accordance with an instruction by the control computer 21. In response to the control signal sent from the deflector control unit 24, the deflector 5 forms a deflected electric field or deflected magnetic field to properly deflect the electron beam EB in the X-direction and the Y-direction so that the surface of the subject 100 is scanned.

A secondary electron, a reflected electron, and a back scattering electron (hereinafter briefly referred to as “secondary electrons”) 2 are generated from the surface of the subject 100 by the irradiation of the electron beam EB. The secondary electrons 2 are detected by the detector 7, and a detection signal is sent to the signal processing unit 25 accordingly. In the present embodiment, the electron beam EB corresponds to, for example, a charged particle beam, and the secondary electrons 2 correspond to, for example, secondary charged particles.

The detection signal from the detector 7 is processed by the signal processing unit 25 and then sent to the first image generating unit 31. The first image generating unit 31 generates an image (SEM image) of the pattern formed on the surface of the subject 100 from the signal sent from the signal processing unit 25. The SEM image is displayed by the display device 29 via the control computer 21, and also stored in the storage device 28.

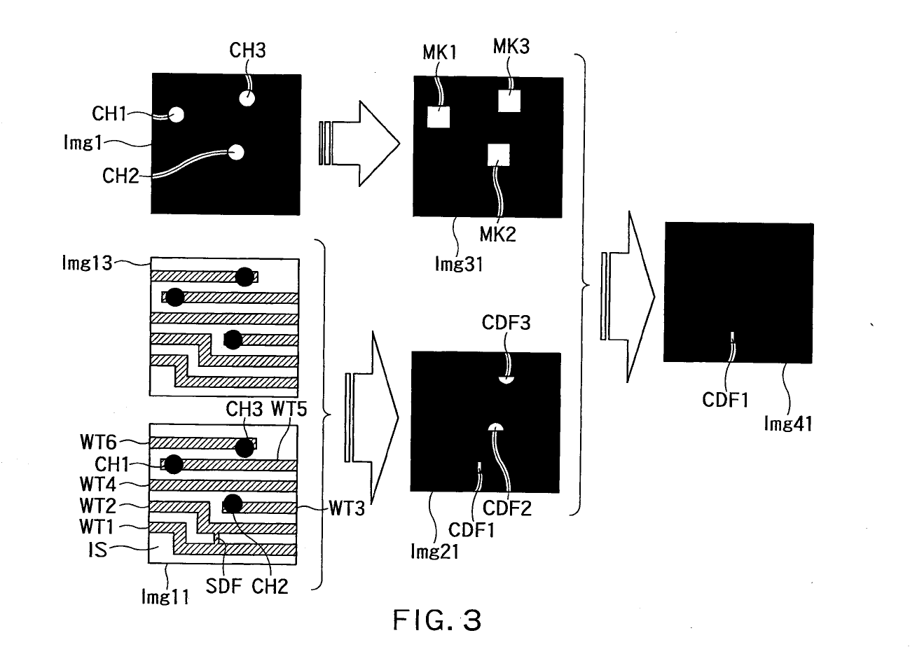

The absorbed current acquiring unit 53 measures an electric current absorbed in a substrate S from the electron beam EB irradiated to the subject 100, and sends the measurement result to the second image generating unit 51. The second image generating unit 51 processes the measurement signal from the absorbed current acquiring unit 53, and then generates an absorbed current image (see the sign Img1 in FIG. 3).

The defect detection unit 33 takes the SEM image or the absorbed current image out of the storage device 28 to extract coordinates of a defect in the inspection target pattern in accordance with a later-described procedure using the technique of a die-to-die inspection or a cell-to-cell inspection. The detection result is sent to the control computer 21, and displayed by the display device 29 and also stored in the storage device 28.

The stage 10 is movable in the X-direction, the Y direction, and the Z-direction. The actuator 12 moves the stage 10 in accordance with a control signal which is generated by the stage control unit 26 in response to an instruction from the control computer 21.

The input device 20 is an interface for inputting the following information to the control computer 21: an electron beam condition, the kind of inspection target pattern, the coordinate position of an inspection area, and various thresholds for defect detection.

A recipe file that describes the procedure of a later-described defect inspection is stored in the storage device 28. The control computer 21 reads this recipe file to conduct a defect inspection. Inspection conditions input from the input device 20 such as later-described first and second EB irradiation conditions (SEM condition) are also stored in the storage device 28.

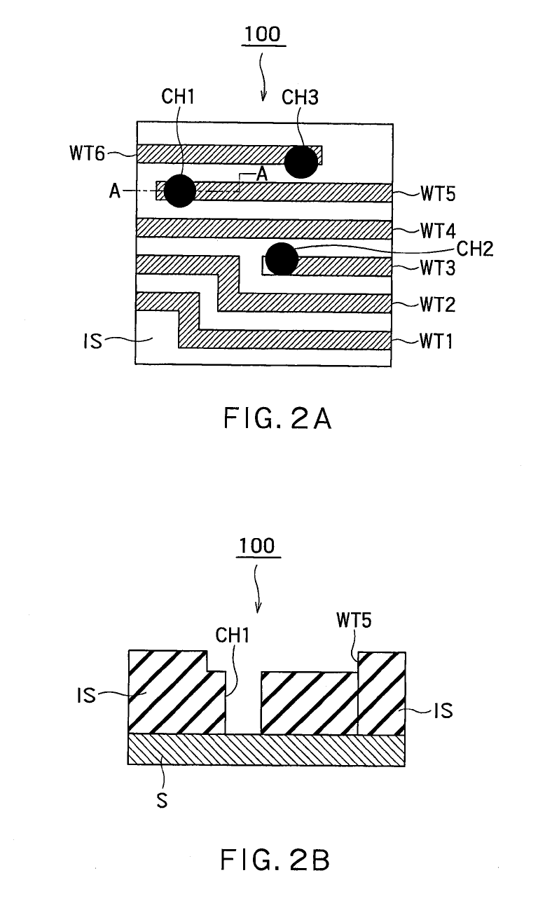

The defect inspection using the defect inspection apparatus 1 shown in FIG. 1 is described with reference to FIG. 2A to FIG. 6C.

FIG. 2A shows an example of pattern layout in a given die in the subject 100. FIG. 2B shows an example of a sectional view taken along the line A-A in FIG. 2A.

The subject 100 shown in FIG. 2A and FIG. 2B includes the substrate S, an insulating film such as an oxide film IS formed on the substrate S, and wiring trenches WT1 to WT6 formed by selectively removing parts of the oxide film IS. The subject 100 also includes contact holes CH1 to CH3 formed so that parts of the oxide film IS are selectively removed in the wiring trenches WT3, WT5, and WT6 to expose the surface of the substrate S.

As shown in FIG. 2A, the wiring trenches WT3, WT5, and WT6 are larger in dimension but shallower than the contact holes CH1 to CH3, and have relatively low aspect ratios.

On the other hand, the contact holes CH1 to CH3 are fabricated to be smaller in dimension but deeper than the wiring trenches WT3, WT5, and WT6, and have relatively high aspect ratios.

In the present embodiment, the wiring trenches WT1 to WT6 are patterns targeted for defect inspection, and the contact holes CH1 to CH3 are patterns that are not targeted for defect inspection. That is, in the present embodiment, the contact holes CH1 to CH3 correspond to, for example, a first pattern, and the wiring trenches WT1 to WT6 correspond to, for example, a second pattern.

In the defect inspection, first, the control computer 21 of the defect inspection apparatus 1 draws the first EB irradiation condition (SEM condition) from the storage device 28. In the present embodiment, the first EB irradiation condition includes a condition in which the contact holes CH1 to CH3 alone are enhanced in the SEM image, more specifically, a high-energy condition with a high acceleration voltage of about 10 keV or more, and an EB condition in which later-described potential contrast is obtained. In the present embodiment, the first EB irradiation condition (SEM condition) corresponds to, for example, a first charged particle irradiation condition.

The control computer 21 generates various control signals in accordance with the first EB irradiation condition to irradiate the electron beam EB toward the substrate S from the electron gun 6, causes the electron beam EB to be focused by the condenser lens 4, and then adjusts the focal position by the objective lens 3 to scan the surface of the substrate S with the deflector 5.

The absorbed current acquiring unit 53 measures the electric current absorbed in the substrate S out of the electron beam EB irradiated to the substrate S, and then sends the measurement signal to the second image generating unit 51. The second image generating unit 51 generates an absorbed current image of the substrate S under the first EB irradiation condition from the measurement signal coming from the absorbed current acquiring unit 53. The generated absorbed current image is sent to the storage device 28 via the control computer 21, and stored in the storage device 28. The absorbed current image thus acquired has contrast that clearly shows the contact holes CH1 to CH3 alone as indicated by the sign Img1 in FIG. 3. In the present embodiment, the absorbed current image generated by the absorbed current acquiring unit 53 and the second image generating unit 51 corresponds to, for example, a first image.

The defect detection unit 33 then takes out the absorbed current image from the storage device 28 to extract coordinates of the contact holes CH1 to CH3. In the present embodiment, the coordinates of the contact holes CH1 to CH3 correspond to, for example, first coordinates.

The defect detection unit 33 then sets a region by providing a predetermined amount of margin in the extracted coordinates, and defines this region as a mask region. Examples of the mask region obtained regarding, for example, the sign Img1 in FIG. 3 are indicated by the signs MK1 to MK3 in an image Img31 in FIG. 3.

In the setting of the mask region, it is preferable to use a conforming article which has been already ascertained to be free of the displacements of the contact holes. However, if the size of margin that can cover normally possible displacement is set, an image of the subject 100 may be used. As the value of margin, for example, about 10% of the width of each of the wiring trenches WT3, WT5, and WT6 is used.

Although the rectangular mask region is set in this example, the mask region is not exclusively rectangular, and, for example, a circular mask region may be set.

In the present embodiment, the mask region is set die by die. However, when there is a small variation of lithography in a predetermined range, for example, in the same lot, contact hole coordinates specified in one die may be applied to another die. In this case, the set mask region can be applied to another die, for example, in the same lot, so that the efficiency of defect inspection improves.

The set mask region is sent to the storage device 28 via the control computer 21, and stored in the storage device 28.

The control computer 21 then draws the second EB irradiation condition (SEM condition) from the storage device 28. In the present embodiment, an EB irradiation condition which provides higher contrast to open defects and short-circuit defects in the wiring trenches than any other EB irradiation conditions is selected as the second EB irradiation condition. More specifically, an EB irradiation condition (e.g. a probe current of several nA to pA order at an acceleration voltage of about 1 keV or less) which provides a higher secondary-emission ratio and which most clearly shows the shape of a pattern is selected (the SEM image obtained by the second EB irradiation condition (SEM condition) is hereinafter referred to as a “shape contrast image”). In the present embodiment, the second EB irradiation condition (SEM condition) corresponds to, for example, a second charged particle irradiation condition.

The control computer 21 generates various control signals in accordance with the second EB irradiation condition to irradiate the electron beam EB toward the substrate S from the electron gun 6, causes the beam flux to be adjusted by the condenser lens 4, and then adjusts the focal position by the objective lens 3 to scan the surface of the substrate S with the deflector 5.

The secondary electrons 2 are generated from the surface of the substrate S by the irradiation of the electron beam EB and detected by the detector 7, and a detection signal is sent to the signal processing unit 25 accordingly. The signal processing unit 25 processes the detection signal from the detector 7 and then sends the signal to the first image generating unit 31. The first image generating unit 31 generates an inspection image (SEM image) from the signal sent from the signal processing unit 25. The SEM image is displayed by the display device 29 via the control computer 21, and also stored in the storage device 28.

An example of an inspection image is shown in FIG. 3 as the image Img11. In the image Img11, the wiring trenches WT1 and WT2 have short-circuited in the vicinity of the contact hole CH2, and produced a defect SDF.

A reference image Img13 in FIG. 3 is an example of an inspection image acquired, under the same condition as an electron beam condition (SEM condition) where the image Img11 is obtained, from a nondefective die which has the same layout in a region different from the region where the image Img11 is obtained among the regions of the subject 100 and which is free of either an inter-wiring short circuit or opening in the wiring line.

As obvious from the contrast with the image Img13, both the contact holes CH2 and CH3 are displaced in the image Img11, and the degrees of the displacements are within the range of allowance.

In the present embodiment, the image Img11 corresponds to, for example, a second image, the image Img13 corresponds to, for example, a reference image, and the region where the reference image Img13 has been acquired corresponds to, for example, a reference region.

The defect detection unit 33 then takes out the inspection image and the reference image from the storage device 28, and generates a difference image of these images by image processing. The generated difference image is displayed by the display device 29 via the control computer 21, and also stored in the storage device 28.

The above-mentioned image is described by way of example. As shown in FIG. 3, the defect detection unit 33 generates a difference image of the inspection image Img11 and the reference image Img13, and outputs this difference image as a difference image Img21. The difference image Img21 includes defect candidates CDF1 to CDF3 including false defects CDF2 and CDF3 from the contact holes CH1 to CH3. In the present embodiment, coordinates of all the defect candidates correspond to, for example, second coordinates.

The defect detection unit 33 then takes out the difference image and the mask region from the storage device 28, and checks the difference image against the mask region to exclude the defect candidates in the mask region from the defect candidates in the difference image. As a result, defect coordinate information in which the false defects from the contact holes are removed is extracted.

The above-mentioned example is described in more detail. As shown in FIG. 3, the defect detection unit 33 checks the difference image Img21 against a mask region Img31 to exclude, from the defect candidates CDF1 to CDF3, the defect candidates CDF2 and CDF3 which are the false defects originating from the displacements of the contact holes CH1 to CH3, and only extracts the defect candidate CDF1 as a defect as shown in an image Img41.

Thus, according to the present embodiment, the mask region is set from the absorbed current image acquired under the high-energy electron beam condition (SEM condition) with a high acceleration voltage, so that the false defects that are not targeted for defect inspection can be accurately removed.

Although the absorbed current image is used in the setting of the mask region in the case described above by way of example, the absorbed current image is not exclusively used. It is also possible to set the mask region from an SEM image acquired under the high-energy electron beam condition (SEM condition) with a high acceleration voltage.

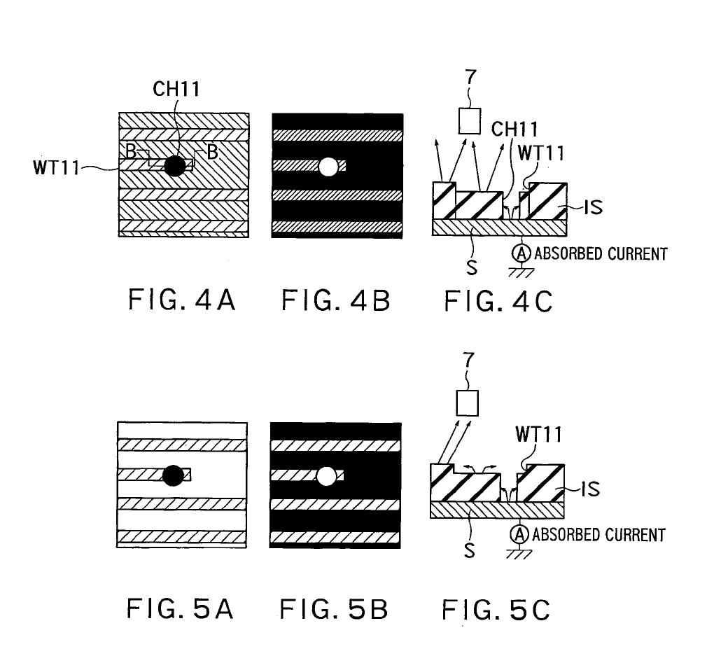

If the high-energy EB condition (SEM condition) with a high acceleration voltage of, for example, 10 keV or more is used to irradiate the electron beam EB to the subject 100, low-energy secondary electrons which have generated from within the contact hole having a high aspect ratio and which can be detected mainly by the detector 7 are absorbed into the sidewall of the contact hole pattern, and cannot come out on the surface of the oxide film IS, as shown in a sectional view of FIG. 4C. Therefore, as indicated by the sign CH11 in FIG. 4A, dark contrast is obtained regarding the contact holes.

On the other hand, the penetration distance of electrons is greater in the wiring trench having a low aspect ratio, for example, the wiring trench WT11 in FIG. 4C, so that the low-energy secondary electrons mainly detected by the detector 7 become insensitive to the shape change of the surface. Therefore, in an SEM image to be obtained, the wiring trench WT11 is brighter, and the contrast difference between the wiring trench WT11 and the oxide film IS on the surface is reduced. As a result, the first image generating unit 31 can form an SEM image in which the contact hole pattern CH11 is enhanced as shown in FIG. 4A. The generated SEM image is sent to the storage device 28 via the control computer 21, and stored in the storage device 28. In this example, the SEM image obtained under the high-energy EB condition with a high acceleration voltage corresponds to, for example, the first image.

The defect detection unit 33 takes out the SEM image from the storage device 28 to extract a contact hole, in the example shown in FIG. 4A, coordinates of the contact hole CH11. The defect detection unit 33 then sets a mask region by providing a predetermined amount of margin in the extracted coordinates.

Subsequently, as in the above-described example using the absorbed current image, the defect detection unit 33 generates a difference image (see Img21 in FIG. 3) from the inspection image (see Img11 in FIG. 3) and the reference image (see the sign Img13 in FIG. 3), and checks the obtained difference image against the mask region to exclude defect candidates in the mask region among the defect candidates in the difference image. As a result, defect coordinate information in which the false defects from the contact holes are removed is extracted.

However, the problem associated with the use of the high-energy electron beam condition (SEM condition) is that the S/N of the SEM image to be obtained is low. This is because the secondary electrons emitted from the pattern surface include high-energy reflected electrons in addition to the above-mentioned low-energy secondary electrons, and if the high-energy electron beam condition (SEM condition) is used, the ratio of the high-energy reflected electrons increases, and low-energy secondary electrons mainly collected by the detector 7 decrease.

Therefore, it is important to detect not only the low-energy secondary electrons but also the high-energy secondary (reflected) electrons, but the collection of the high-energy secondary (reflected) electrons by the detector 7 is extremely difficult in design, so that most of these electrons are absorbed into the sidewall of the electron beam column 9. Thus, the detection efficiency of the high-energy secondary (reflected) electrons is low.

In contrast, as described above, the absorbed current acquiring unit 53 and the second image generating unit 51 measure the electric current absorbed in the substrate S and generate the absorbed current image shown in FIG. 4B. If a mask region is set from this absorbed current image, the S/N can be improved, and the accuracy of the extraction of the contact hole coordinates can be improved. This is also obvious from, for example, the comparison of contrast between FIG. 4A and FIG. 4B.

For ease of understanding, an SEM image, an absorbed current image, and an emission aspect of the secondary (reflected) electrons in the case where the low-energy electron beam condition (SEM condition) with a low acceleration voltage is used are shown in FIG. 5A to FIG. 5C in comparison with the case where the high-energy electron beam condition (SEM condition) with a high acceleration voltage is used.

Although the mask region is set from the absorbed current image or the SEM image acquired under the high-energy electron beam condition (SEM condition) with a high acceleration voltage in the above explanation, the present invention is not limited thereto. It is also possible to set the mask region by using a later-described potential contrast image.

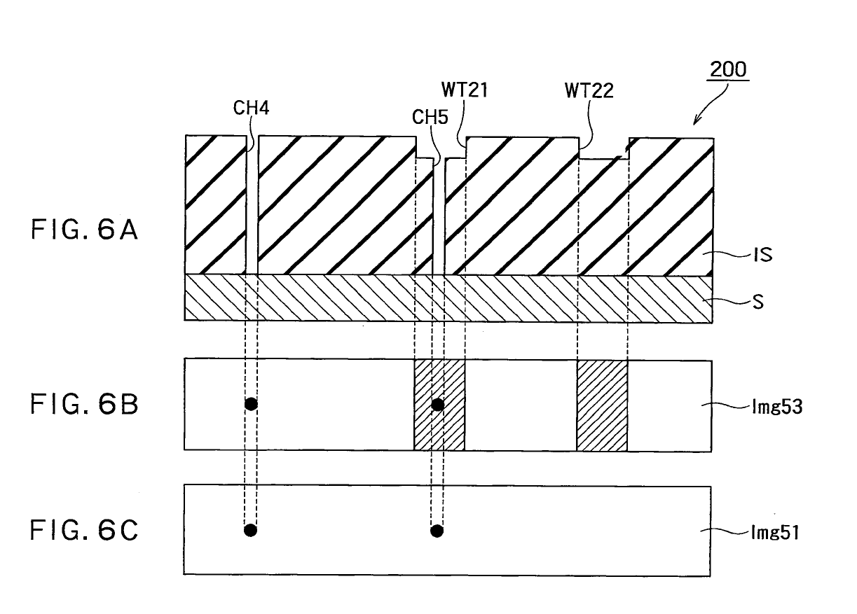

FIG. 6A is an example of a partial sectional view showing another example of a subject. In a subject 200 shown in FIG. 6A, an insulating film such as an oxide film IS is formed on the substrate S, parts of the oxide film IS are selectively removed to form wiring trenches WT21 and WT22, and another part of the oxide film IS is removed so that the surface of the substrate S is exposed to form a contact hole CH4. Moreover, a part of the oxide film IS is selectively removed in the wiring trench WT21 so that the surface of the substrate S is exposed, and a contact hole CH5 is thus formed.

The wiring trenches WT21 and WT22 are floating patterns which are formed in the surface layer of the oxide film IS and in which electrons applied by the electron beam EB cannot escape to the substrate S.

On the other hand, the contact holes CH4 and CH5 are conducted to the substrate S, and the electrons applied by the electron beam EB escape to the substrate S.

In this case, if the electron beam EB is irradiated in the SEM condition with a probe current of several ten nA order at a low acceleration voltage of about 1 keV or less, a potential contrast image indicated by the sign CH51 in FIG. 6C, for example, can be obtained. The mask region indicated by the sign CH31 in FIG. 3 can also be set by the use of the potential contrast image thus obtained.

When this SEM condition is used, the absorbed current acquiring unit 53 and the second image generating unit 51 are not used in the defect inspection apparatus shown in FIG. 1, and the potential contrast image can be acquired by the detector 7, the signal processing unit 25, and the first image generating unit 31 as in the case where the shape contrast image is acquired.

FIG. 6B shows an example of a shape contrast image Img53 obtained by irradiating the electron beam EB to the subject 200 under an SEM condition with a probe current of several nA to pA order at an acceleration voltage of 1 keV or less.

According to the defect inspection apparatus in at least one embodiment described above, a mask region is set regarding a pattern that is not targeted for inspection, and this mask region is checked against the difference image between the inspection image and the reference image, so that a detection target defect can be accurately separated from other defects. Thus, the detection target defect can be detected with high sensitivity.

In the setting of the mask region, a method that uses design data is also theoretically possible. For example, a conceivable method is to previously extract coordinates of a contact hole in the design data, set a mask region from obtained coordinate data, and remove false defects originating from the contact hole by checking the mask region against the above-mentioned difference image.

However, as described above, the position of the contact hole actually formed on the substrate is different from the coordinates on the design data depending on, for example, the alignment accuracy of the stage 10. In order to avoid this problem, it is necessary to set a mask region that takes into consideration a high tolerance for each of the enormous number of contact holes, for example, a tolerance over ten times the margin used for the setting of the above-mentioned mask region. The problem associated with the use of such a high tolerance is that an extremely large area becomes the target range of the mask region, and the target defect to be originally detected is excluded together.

In contrast, according to the defect inspection apparatus in at least one embodiment described above, an image is acquired from the pattern actually formed on the substrate, and a mask region is set with a small margin from the obtained image, so that the detection target defect is not excluded and can be detected with high sensitivity.

(2) Defect Inspection Method

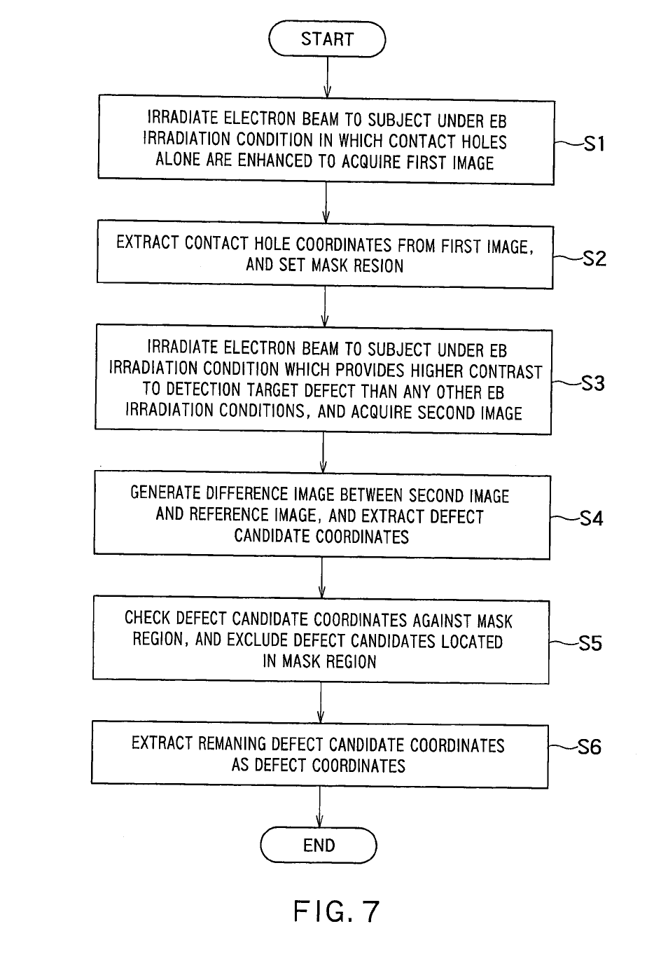

A defect inspection method according to one embodiment is described with reference to a flowchart in FIG. 7.

Before the defect inspection, patterns on a subject are sorted into patterns target for inspection and patterns that are not targeted for inspection. In the subject 100 shown in FIG. 2A by way of example, the patterns WT1, WT2, and WT4 of the wiring trenches formed in the surface layer of the oxide film IS are specified as the inspection target patterns, and the contact holes CH1 to CH3 formed in the wiring lines WT5, WT3, and WT6 are specified as the patterns that are not targeted for inspection.

First, an electron beam is irradiated to the subject under an EB irradiation condition in which the contact holes alone are enhanced to acquire a first image (step S1).

The EB irradiation condition in which the contact holes alone are enhanced includes the high-energy EB condition (SEM condition) with a high acceleration voltage of, for example, 10 keV or more, and the SEM condition with a probe current of several ten nA order at a low acceleration voltage of, for example, 1 keV or less.

Under the high-energy EB condition (SEM condition) with a high acceleration voltage, for example, an absorbed current image indicated by the absorbed current image Img1 in FIG. 3 and the SEM image shown in FIG. 4A are acquired as the first image.

Under the SEM condition with a probe current of several ten nA order at a low acceleration voltage of, for example, 1 keV or less, for example, the wiring trenches WT21 and WT22 in the subject 200 shown in FIG. 6A are specified as the inspection target patterns, and the contact holes CH4 and CH5 are specified as the patterns that are not targeted for inspection. As a result, for example, a potential contrast image indicated by the sign Img51 in FIG. 6C is acquired as the first image.

The acquired first image is then processed to extract coordinates of the contact holes, and a mask region in which a predetermined amount of margin is provided in the extracted coordinates is set (step S2). In the present embodiment, coordinates of the contact holes correspond to, for example, first coordinates.

An electron beam is then irradiated to the subject under an EB irradiation condition which provides higher contrast to the detection target defect than any other EB irradiation conditions, and a second image is acquired (step S3).

Here, the EB irradiation condition which provides higher contrast to the detection target defect than any other EB irradiation conditions includes, for example, an EB irradiation condition (e.g. a probe current of several nA to pA order at an acceleration voltage of, for example, 1 keV or less) which provides a higher secondary-emission ratio and which most clearly shows the shape of a pattern.

A difference image between the obtained second image and the reference image is then generated, and defect candidate coordinates are extracted (step S4).

As the reference image, an SEM image obtained regarding a conforming article which is a die or a cell having the same layout as the layout of the inspection region and which has been already ascertained to be free of defects may be used, as described above. However, when a die-to-die or cell-to-cell defect inspection technique is used, an image obtained regarding an adjacent die or an adjacent pattern may be used.

The defect candidate coordinates extracted from the difference image not only include coordinates of short-circuit defects and open defects in the wiring trenches targeted for inspection but also include coordinates of false defects resulting from slight shape changes and displacements of the contact holes that are not targeted for inspection. In the present embodiment, the defect candidate coordinates including the false defects resulting from such contact holes correspond to, for example, second coordinates.

The extracted defect candidate coordinates are then checked against the mask region, and defect candidates located in this mask region are excluded (step S5). Consequently, the coordinates of the false defects resulting from slight shape changes and displacements of the contact holes can be excluded.

Finally, remaining defect candidate coordinates are extracted as defect coordinates targeted for inspection (step S6).

According to the defect inspection method in at least one embodiment described above, a mask region is set regarding a pattern that is not targeted for inspection, and this mask region is checked against the difference image between the inspection image and the reference image, so that a detection target defect can be accurately separated from other defects. Thus, the detection target defect can be detected with high sensitivity.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A defect inspection apparatus comprising:
a charged particle source configured to generate a charged particle beam and irradiate the charged particle beam to a subject comprising a first pattern and a second pattern;
a detection unit configured to detect secondary charged particles from the subject by the irradiation of the charged particles and output a signal;
a first image generating unit configured to process the signal to generate an image; and
a defect detection unit configured to extract first coordinates of the first pattern from an image obtained by irradiating a charged particle beam to the subject under a first charged particle irradiation condition, to set a mask region in which a predetermined margin is provided in the first coordinates, take a difference between an image obtained by irradiating a charged particle beam to the subject under a second charged particle irradiation condition and a reference image obtained by irradiating a charged particle beam to a reference region different from a subject region based on the same layout as the subject under the second charged particle irradiation condition, and to check the difference against the mask region to detect a defect in the second pattern,
wherein the first charged particle irradiation condition is a condition in which higher contrast is obtained regarding the first pattern than the second pattern in the image obtained by irradiating the charged particle beam to the subject.

2. The apparatus of claim 1,
wherein the subject comprises a substrate on which the first and second patterns are formed,
the apparatus further comprises a second image generating unit configured to detect a current absorbed in the substrate out of the irradiated charged particle beam, and process an obtained current value to generate an absorbed current image,
energy of the charged particle beam by the first charged particle irradiation condition is higher than energy of the charged particle beam by the second charged particle irradiation condition, and
the defect detection unit extracts the first coordinates by processing the absorbed current image obtained under the first charged particle irradiation condition.

3. The apparatus of claim 1,
wherein the first charged particle irradiation condition is a condition to obtain a potential contrast image.

4. The apparatus of claim 1,
wherein the second pattern is a pattern of a wiring line.

5. The apparatus of claim 1,
wherein the first pattern is a pattern of a contact hole.

6. A defect inspection method comprising:
generating a charged particle beam under a first charged particle irradiation condition, and generating a first image from a signal obtained by irradiating the charged particle beam to a subject comprising a first pattern and a second pattern;
extracting first coordinates of the first pattern from the first image;
setting a mask region in which a predetermined margin is provided in the first coordinates;
generating a charged particle beam under a second charged particle irradiation condition, irradiating the charged particle beam to a subject region of the subject, and generating a second image from a signal obtained by detecting second charged particles generated from the subject;
taking a difference between the second image and a reference image which is obtained by irradiating a charged particle beam to a reference region different from the subject region based on the same layout as the subject under the second charged particle irradiation condition; and
checking the difference against the mask region to detect a defect in the second pattern,
wherein the first charged particle irradiation condition is a condition in which higher contrast is obtained regarding the first pattern than the second pattern in the image obtained by irradiating the charged particle beam to the subject.

7. The method of claim 6,
wherein the subject comprises a substrate on which the first and second patterns are formed,
the method further comprises detecting a current absorbed in the substrate out of the irradiated charged particle beam, and processing an obtained current value to generate an absorbed current image,
energy of the charged particle beam by the first charged particle irradiation condition is higher than energy of the charged particle beam by the second charged particle irradiation condition, and
the first coordinates are extracted by processing the absorbed current image obtained under the first charged particle irradiation condition.

8. The method of claim 6,
wherein the first charged particle irradiation condition is a condition to obtain a potential contrast image.

9. The method of claim 6,
wherein the second pattern is a pattern of a wiring line.

10. The method of claim 6,
wherein the first pattern is a pattern of a contact hole.
